(19) United States
(12) Patent Application Publication
(10) Pub. No.: US 2005/0161252 A1
(43) Pub. Date: Jul. 28, 2005

(54) Method for fitting out and soldering a circuit board, reflow oven and circuit board for said method

(76) Inventor: Dietmar Birgel, Schopfheim (DE)

Correspondence Address: BACON & THOMAS, PLLC, 625 SLATERS LANE, FOURTH FLOOR, ALEXANDRIA, VA, 22314, US

(21) Appl. No.: 10/507,213

(22) PCT Filed: Mar. 15, 2003
(86) PCT No.: PCT/EP03/02627

(30) Foreign Application Priority Data
Mar. 15, 2002 (DE) 102 11 647.4

(51) Int. Cl. H05K 7/18; H05K 3/34

(52) U.S. Cl. 174/260; 29/840

(57) ABSTRACT

A method for populating and soldering a circuit board, which is populated with a wired, electrical component having at least one connection wire or pin and a housing or casing thermally critical for conventional, automatic soldering methods. Additionally, a reflow oven for the soldering of the circuit board and a circuit board for such method are discussed. Soldering of the thermally critical component in the reflow oven is enabled by using the circuit board itself for the thermal shielding of the thermally critical THT-components against the heat energy acting on the circuit board and required for the soldering. The circuit boards are placed on frames for this purpose, for example, and transported through the reflow oven in such a manner that the thermally critical components are arranged on the under side of the circuit board facing away from the heat energy.

The invention relates to a method for populating and soldering a circuit board, to a reflow oven for soldering the circuit board and to a circuit board for said method. Especially, the invention relates to such circuit boards, which are populated with a wired electrical component having at least one connection wire or pin and a housing or casing thermally critical for conventional automatic soldering processes.

A basic consideration is that one strives currently to perform the populating, respectively soldering, of circuit boards as much as possible by machine, in order to optimize manufacturing costs and effort.

The currently best-known machine soldering methods for the soldering of electrical and electronic components on a circuit board are the so-called wave-soldering method and the so-called reflow soldering method. These two methods are described in detail in comparison with other conventional methods of soldering in the article of Dr.-Ing. Hans Bell entitled “Gibt es einen Paradigmenwechsel in der Löttechnik (Is There a Paradigm-Shift in Soldering Technology?”, in the journal “VTE—AUFBAU-UND VERBINDUNGSTECHNIK IN DER ELEKTRONIK”, No. 6/December 1999, Pages 297 to 301. The author describes therein the procedures and components to be used in the various solder processes for populating a circuit board and the details of performing the soldering.

In most currently available reflow ovens, a more or less diffuse, hot gas stream of pure hot air or a heated special gas is supplied perpendicularly onto the circuit board surface to be soldered. The circuit boards are heated upon entering into such a reflow oven and then transported into the actual working, i.e. soldering, area. Usual temperatures in the area of the circuit board surface to be soldered rise to 220° C. at a residence time of up to 30 s.

A great problem with soldering in a reflow oven is presented currently, however, by those components that cannot withstand the thermal conditions in usual reflow ovens and which become deformed or even destroyed under the conditions existing therein. Thus, for example, plug connectors, flex connectors, DIP-switches and other components, also semiconductor components, conventionally supplied with a plastic housing, are not suited for the usual reflow ovens.

Moreover, there are still other components which are used on circuit boards and which are not suited for soldering in reflow ovens, because they include non-heat-resistant parts, adhesives and/or coatings.

Components, which cannot withstand the temperatures existing in reflow ovens during the soldering process, cannot participate in the cost-favorable, machine populating and soldering in reflow overs, but, instead, require additional, labor-intensive and, consequently, cost-intensive, individual-, respectively special, populating in plural, special process steps.

Some of these components are available in special embodiments resistant to high temperatures, but they are markedly more expensive than the usual components. Thus, their use is frequently uneconomic, since they negate the cost savings which would otherwise be achieved by a purely machine populating and soldering procedure.

It is, therefore, an object of the present invention is provide a method for populating and soldering a circuit board, a reflow oven and a circuit board for such a method, permitting also those components, which are not resistant to the temperatures existing in reflow ovens during soldering, to be used in a machine soldering procedure, without requiring complicated and cost-intensive, individual populating and/or manual, individual soldering.

This object is achieved according to the invention by a first variant of a method for populating and soldering a circuit board having a first side and a second side and at least one wired, electrical component (THT-component) with at least one connection wire or connection pin and a housing or casing thermally critical for conventional, automatic soldering technology, which method includes the following method steps:
a) the THT-component is populated on the first side of the circuit board, such that its connection wire or connection pin extends from the first side through a hole and emerges from the hole on the second side of the circuit board in the area of a solder contact surface printed with a solder paste; and
b) the thus-populated circuit board is placed in a reflow oven for soldering, wherein the first side populated with the THT-component is at least partially, essentially shielded from a heat or energy supply effecting the soldering.

This object is also achieved according to the invention by a second variant of a method for populating and soldering a circuit board having a first side and a second side and at least one wired, electrical component (THT-component) with at least one connection wire or connection pin and a housing or casing thermally critical for conventional, automatic soldering technology, which method includes the following method steps:
a) the THT-component is populated on the first side of the circuit board, such that its connection wire or connection pin extends from the first side through a hole and emerges from the hole on the second side of the circuit board in the area of a solder contact surface printed with a solder paste; and
b) the thus-populated circuit board is placed in a reflow oven for soldering, wherein the first side populated with the THT-component is thermally separated from a heat or energy supply acting on the second side of the circuit board for the soldering and wherein, by suitable means, a temperature difference of at least 28° C. can be achieved between the first and second sides.

In a preferred form of embodiment of the method of the invention, for populating the second side of the circuit board with at least one SMD-component, solder paste is applied to solder contact surfaces provided therefor, and, following populating of the second side of the circuit board with the SMD-component, such, together with the connection wire of the THT-component, are soldered in a process step in the reflow oven.

In another preferred embodiment of the method of the invention, also the first side of the circuit board is populated with at least one SMD-component.

A further preferred form of embodiment of the method of the invention includes the following process steps:
a) printing of solder paste onto the first side of the circuit board;
b) populating the first side with SMD-components;
c) soldering the SMD-components of the first side in the reflow oven;
d) populating the first side with at least one THT-component;
e) printing solder paste on the second side;
f) populating the second side with SMD-components, and
g) soldering SMD-components of the second side and the one or more THT-components in the reflow-oven.

Further forms of embodiments of the method of the invention concern a dressing of connection wires of the THT-components before the printing of the solder paste onto the second side of the circuit board.

Still other forms of embodiments of the method of the invention concern a securement of THT-components on the circuit board.

Yet another preferred form of embodiment of the method of the invention includes the following method steps:
a) printing solder paste on the first side;
b) applying adhesive on locations of the first side to be populated with THT-components;
c) populating the first side with SMD-components;
d) populating the first side with THT-components;
e) soldering the SMD-components of the first side in the reflow oven;
f) printing solder paste on the second side;
g) populating the second side with SMD-components; and
h) soldering the components of the second side and the THT-components in the reflow oven.

Yet another form of embodiment of the method of the invention concerns a populating of the circuit board with at least one pin-in-hole component (PIH-component).

In a further, preferred form of embodiment of the method of the invention, the first side of the circuit board populated with one or more THT-components is shielded, respectively thermally separated, essentially by the circuit board itself from the heat or energy feed onto the second side for the soldering.

Yet another, preferred form of embodiment of the method of the invention concerns a horizontal arrangement of the circuit board during the traversing of the reflow oven, with the one or more thermally critical THT-components to be soldered being located beneath the circuit board.

Still another preferred form of embodiment of the method of the invention concerns cooling the first side of the circuit board in the reflow oven during the soldering of the second side.

In another preferred form of embodiment of the method of the invention, in the reflow oven, those areas of the circuit board inclined to an above-average uptake of heat energy due to circuit board layout, are covered by a covering preventing or delaying the uptake of heat energy.

In a further, preferred form of embodiment of the method of the invention, in the reflow over, those areas of the circuit board where an above-average uptake of heat energy is desired, are covered by a covering which improves uptake of heat energy.

The above-mentioned object is, furthermore, achieved, according to the invention, by a first variant of a reflow oven for soldering a circuit board having a first and a second side and at least one wired electrical component (“THT-component”) having at least one connection wire or connection pin and a housing or casing thermally critical for conventional automatic soldering technology, wherein the first side of the circuit board populated with the THT-component is shielded during the soldering of the second side of the circuit board, in the area of a contact surface printed with a solder paste and containing a fed-out connection wire of the THT-component, from a heat or energy feed effecting the soldering.

The above-mentioned object is, moreover, achieved, according to the invention, by a second variant of a reflow oven for soldering a circuit board having a first side and a second side and at least one wired electrical component (“THT-component”) having at least one connection wire or connection pin and a housing or casing thermally critical for conventional automatic soldering technology, wherein the first side of the circuit board populated with the THT-component is separated, during the soldering of the second side of the circuit board in the area of a contact surface printed with a solder paste and containing an emerging connection wire of the THT-component, from a heat or energy feed effecting the soldering and wherein a temperature difference between the first and second sides of at least 28° C. can be set by suitable means.

In a preferred form of embodiment of a reflow oven of the invention, the side of the circuit board populated with the one or more THT-components is shielded, respectively thermally separated, essentially by the circuit board itself from the heat or energy feed effecting the soldering.

In another form of embodiment of the reflow oven of the invention, a cooling apparatus is provided therein, by means of which the side of the circuit board populated with the one or more THT-components is cooled during the soldering process.

Yet another form of embodiment of the reflow oven of the invention has at least one infrared radiation source, which delivers energy effecting the soldering.

The above-mentioned object is also achieved by a circuit board for one of the above-described methods of the invention, wherein the circuit board is so designed or embodied that it makes possible locally pre-determinable areas of above-average heat energy uptake in the case of heat energy acting externally on the circuit board.

A preferred form of embodiment of the circuit board of the invention concerns an inner layer of the circuit board, which is so designed, respectively embodied, that in the areas where above-average heat energy absorption is desired, there is always a large-area, metallic and/or electrically conducting part.

The invention involves the idea that thermally sensitive components be so located during the passage through the reflow oven that they are essentially shielded from the heat or energy feed onto the surface of the circuit board to be soldered.

In a preferred form of embodiment, the shielding is most simply achieved by way of the circuit board itself, with this effect being supported in further, preferred forms of embodiment of the invention by supplemental coverings and/or temperature-sinking measures. In another form of embodiment of the invention, the shielding effect of the inventive arrangement of the circuit board is advantageously supported also by a correspondingly selected design, respectively layout, of the circuit board.

The invention will now be described on the basis of examples of preferred forms of embodiments of the invention, with reference to an accompanying drawing, the figures of which show as follows:

FIG. 1 a schematic representation of various components and assemblies on a usual circuit board;

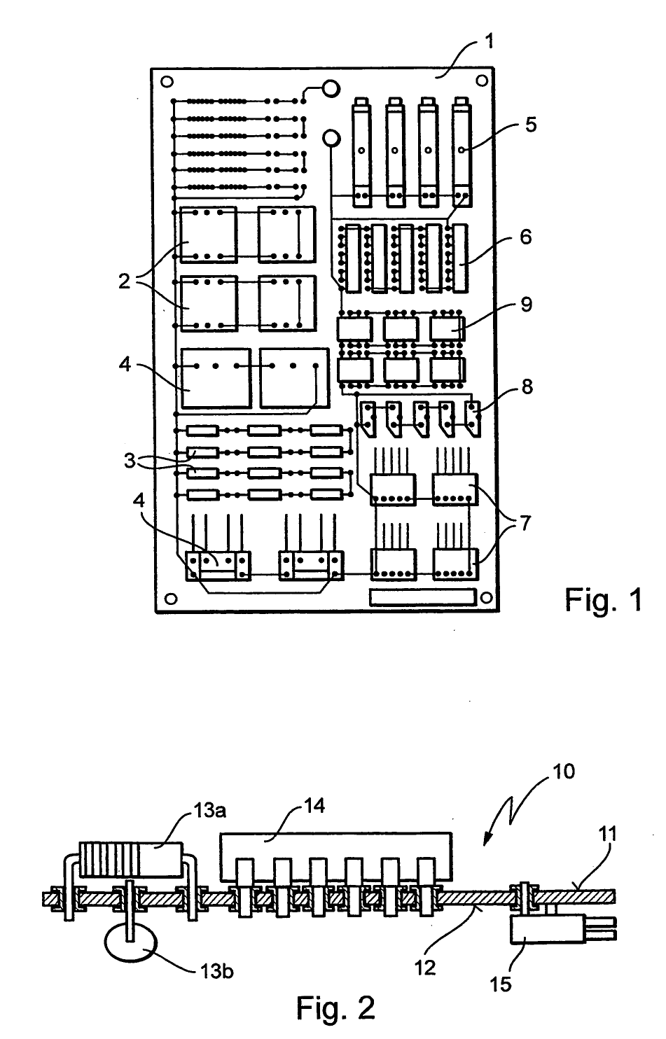

FIG. 2 a schematic representation of another usual arrangement of various components on a circuit board populated on both sides;

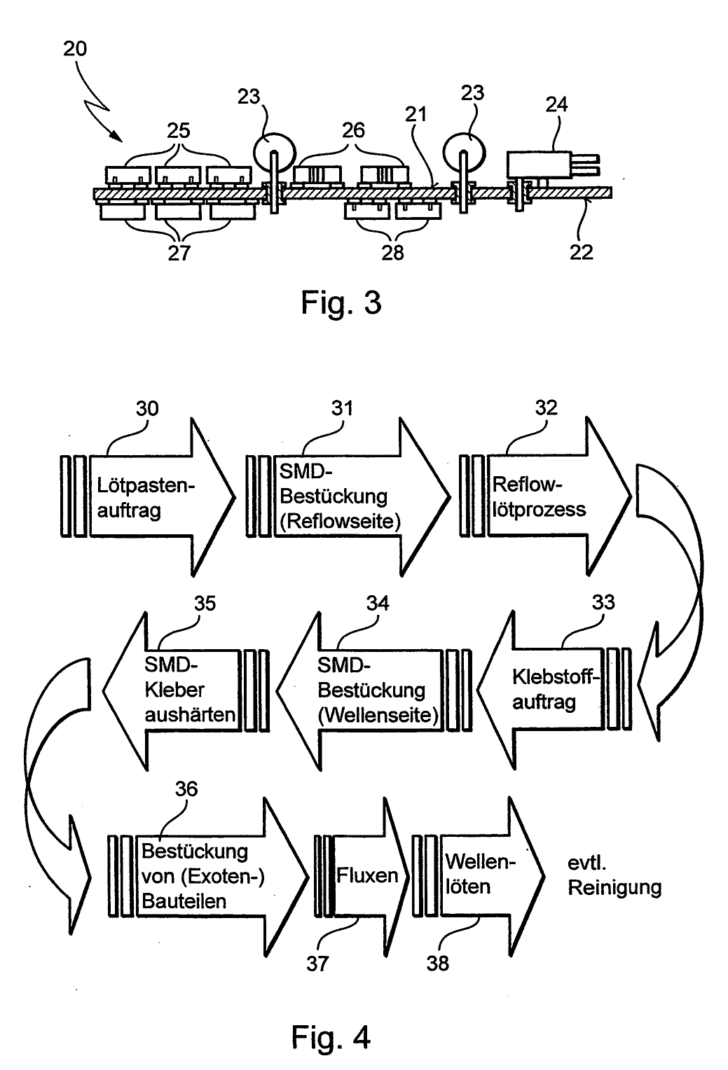

FIG. 3 a schematic representation of a further usual arrangement of various components on a circuit board populated on both sides;

FIG. 4 a schematic representation of the steps of a contemporary, usual method for populating and soldering a circuit board of FIG. 3;

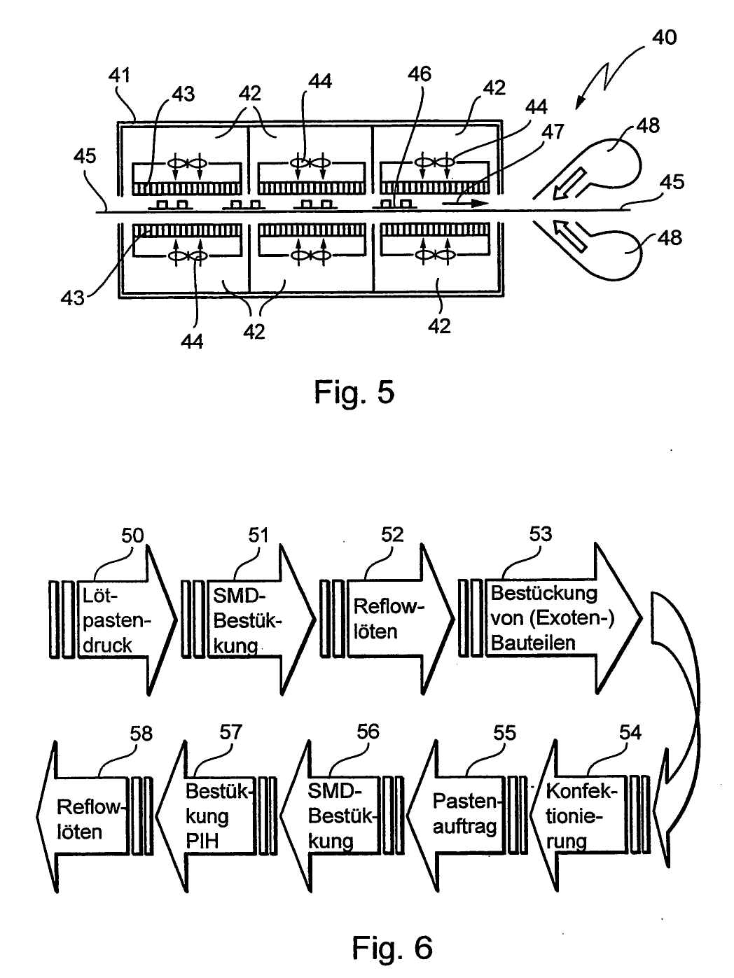

FIG. 5 a schematic representation of a usual reflow oven;

FIG. 6 a schematic representation of the steps of a preferred method of the invention for the populating and soldering of components;

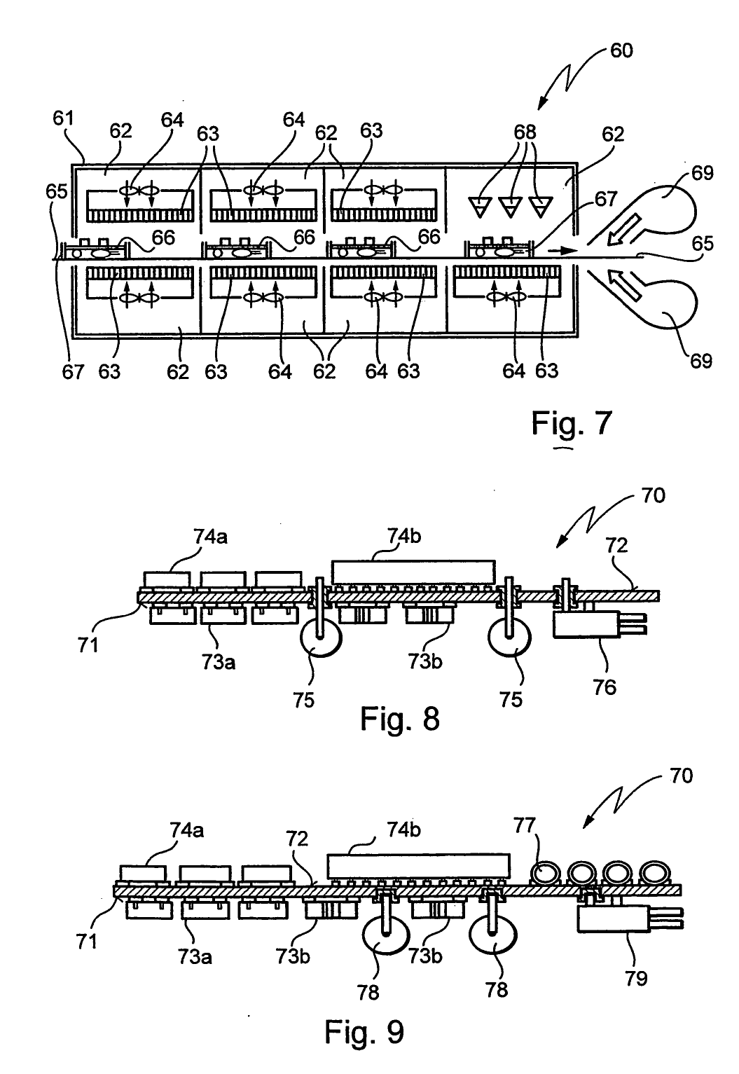

FIG. 7 a schematic representation of a reflow oven of the invention;

FIG. 8 a schematic representation of a further, preferred arrangement of various components on a circuit board of the invention;

FIG. 9 a schematic representation of another preferred arrangement of various components on a circuit board of the invention;

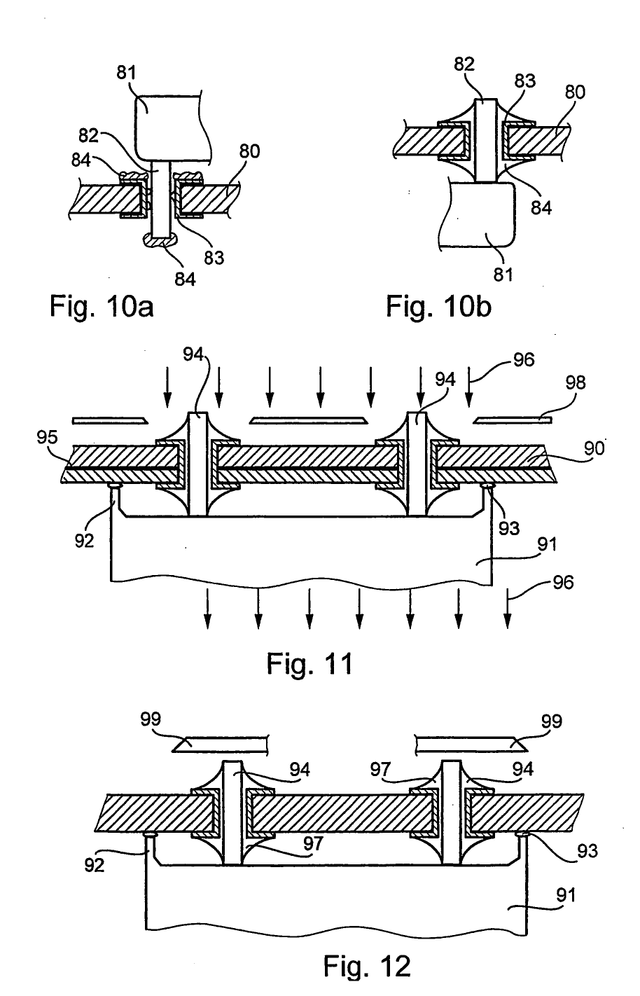

FIG. 10a a schematic representation of a connection location of a connection wire of a component in a usual populating and soldering process;

FIG. 10b a schematic representation of a connection location of a connection wire of a component in a populating and soldering method of the invention;

FIG. 11 a schematic representation of another circuit board of the invention in the soldering process with a thermal shielding; and

FIG. 12 a schematic representation of another circuit board of the invention in the soldering process with a special covering.

For simplification, equal devices, components, etc. are provided with equal reference characters in the drawing.

For clarification of the components used in a conventional circuit board and the problems which arise because of their differing abilities to withstand heat, FIG. 1 presents a schematic example of one such circuit board 1. The following explanations of circuit boards, plus populating and soldering methods, as used to date, serve also to bring out the advances and advantages achieved by the invention.

For simplification, the components are not shown as such, but, instead, are indicated by the populating imprint, or top overlay, of the circuit board 1. Among these components not shown in greater detail are transformers 2, special plugs 4 with large housings, rotary switches 5 and resistors 6. Additionally provided on the circuit board 1 are angle plugs 7, and semiconductor components in TO-package housings 8 and in DIL-package housings 9. The illustrated components are either wired or have connection pins, with the connection wires or pins being stuck through metallized holes at the solder connections of the circuit board 1; they are, therefore, referenced as “THT-components” herein. THT is short for “Through Hole Technique”. Such THT-components are usually soldered in the wave solder bath, or, if they cannot withstand the temperatures existing there or if they deform, they are manually soldered. As already described above, a resort to manual soldering is very costly.

Some of the components illustrated in FIG. 1 can, however, also be provided as so-called PIH-components. PIH is short for “Pin In Hole”. In the case of such components, the connection wires or pins are considerably shortened and so configured that they can be stuck into metallized and solder-paste-printed, blind holes, which are, in such case, constituents of the solder connections of the circuit board 1. If these PIH-components are insensitive to the temperatures and conditions existing in a reflow oven, then they can be soldered therein, arranged standing upright, for example along with SMD-components, should the circuit board also be populated with such.

Another example of a conventional circuit board is shown schematically in FIG. 2 in the form of a side view and cross section of the circuit board. This circuit board 10 is populated both on its first circuit board side 11 and on its second circuit board side 12. By way of example, two THT resistances 13a, 13b are shown, one on each of the sides 11, 12, and a component with a THT-DIL-package housing 14, plus a THT angle plug 15. As is known, in the case of such a circuit board 10, first the first side 11 is populated with the resistor 13a, the DIL-package housing 14, and all other THT-components stuck through the board from this first side, following which soldering is done in a wave bath, for example. Subsequently, on the second side, the other THT-resistor 13b, the angle plug 15, and other THT-components of the second side 12 are populated and manually soldered. Also this is, as is known, a very expensive method. When a component is arranged in the manner of the resistance 13b in FIG. 2, there is also the disadvantage that at least one of the solder locations of the resistance 13b is covered and cannot be checked for quality control.

FIG. 3 shows still another circuit board 20 populated with SMD- and THT-components. Also in the case of the cross section illustrated here, circuit board 20, again, is a board populated on two sides, a first side 21 and a second side 22. Thus, by way of example, the first side 21 carries THT-resistances 23, a THT angle plug 24, and first and second SMD components 25, 26, respectively. Illustrated on the second side 22 of the circuit board 20 are third SMD-components 27 and fourth SMD-components 28.

In conventional manner, the circuit board 20 of FIG. 3 is manufactured according to a method illustrated schematically by FIG. 4. Following an application of a solder paste 30, preferably with a printing process, for example a screen printing process, the first SMD-components 26 and the second SMD-components 27 are populated on the first side 21 of the circuit board 20 (see FIG. 3). This SMD-populating 31 is usually done automatically by an automatic populating machine, using taped SMD-components. Following the populating, the circuit board 20 is soldered in a usual reflow oven, along with other circuit boards to be soldered. An example of such a reflow oven is shown in FIG. 5 and is described below. Following the soldering in the reflow oven, the circuit board is turned over and an application 33 of adhesive is made on its second side 22 at the locations where the SMD components 27 and 28 are to be placed. A subsequent populating 34 of the third and fourth SMD components 27 and 28 is, in turn, accomplished automatically. Following hardening of the adhesive, the THT-components are populated, along with those which cannot be populated fully automatically. In the case of the circuit board shown in FIG. 3, these are, for example, the THT-resistors 23, which are to be soldered on the second side 22.

Among the so-called exotic components are included also those which, due to their non-uniform distribution of mass, require special securement to the circuit board, since they, for example, cannot be sufficiently secured against tipping by a simple adhesive procedure. These components must be held in position on the circuit board by means of snap-in technology or by insertion into a socket or the like, until the soldering is accomplished or even beyond that. Following subsequent fluxing 37, the circuit board 20, usually together with other circuit boards, is sent to wave soldering bath 38, where the components populated in step 36, together with the SMD-components 27 and 28, are soldered. If required, the circuit boards go through an additional cleaning, subsequent to the wave soldering 38.

Even in the case of this FIG. 4-illustrated method, which is modern compared to the above-described manual soldering processes, it is necessary to remove the circuit board 20 from the actual automatic manufacturing line, in order to do the populating with the so-called exotic components, which cannot be handled by completely automatic populating. Such a currently widely accepted method is still involved and cost-intensive.

To complete the just described matters, FIG. 5 illustrates a conventional reflow oven 40, which will be described here briefly in comparison to a later-described reflow oven 60 of the invention, as illustrated in FIG. 7. Thus, with reference to FIG. 5, reflow oven 40 includes, essentially, a housing 41, which is divided internally into a plurality of chambers 42, in order to enable a better temperature control and convection in the individual chambers 42 and a targeted heat-up and soldering of circuit boards 46. Usually, each of the chambers 42 is provided with heat exchangers 43 and blowers 44, both above and below a conveyor belt 45, on which the circuit boards 46 are transported through the reflow oven in the direction of arrow 47. Following exit from the reflow oven 40, often cooling blowers 48 are provided, which serve for the controlled cooling of the soldered circuit boards 46 to ambient conditions.

As already explained above, the internal temperature in usual reflow ovens is a major problem, especially for components whose housings cannot withstand such temperatures over the course of the residence time in the oven. In this connection, attention must be paid to the fact that, in a usual reflow oven 40, such as is illustrated, for example, in FIG. 5, the temperature above the conveyor belt 45 can be as high as 220° C. Usual plastic housings of angle plugs, TO- or DIL-package housings of the THT-embodiment (see also FIG. 1 in this connection) cannot survive such temperatures without deforming and thus placing the functionality of the component in question.

FIG. 6 is a schematic representation of the course of a preferred method of the invention for the populating and soldering of components. With this method, it is possible now to solder also thermally critical components in the reflow oven. Under consideration in this embodiment is the populating and soldering of a circuit board populated on both sides with SMD- and PIH-components; for an example, see FIG. 9. Following a solder paste printing 50 onto a first side of the circuit board, an automated SMD-component-populating 51 is carried out, with the so-populated board then being sent into and through a reflow oven. After the circuit board has cooled, a populating 53 of THT-components and other thermally critical components is performed on the first side of the circuit board. These components have already been described above, especially in the description of FIG. 4 under the label “exotic components”. These components are populated on the first side, i.e., in the case of the THT-components, the connection pins, respectively wires, are stuck through the appropriate holes and through the circuit board, so that they protrude on the second side. Preferably, heavy, exotic components, or such with non-uniform mass distribution, which have a tendency to tilt, are either secured in place by adhesive or they are held in the desired orientation by holders, such as, for example, snap-in securements. In the case of small, respectively light, components, it can also be sufficient to dress the individual connection wires, respectively connection pins, on the other, the second, side of the circuit board, especially by so bending them as to cause the components to be clamped securely in their positions.

For a dressing 54 of the connection wires, respectively connection pins, of the THT-components, the circuit board is turned such that its first side is above and the so-called exotic components are below, thus the exotic components are located beneath the circuit board. If necessary, the connection wires, respectively connection pins, of the THT-components are shortened and/or so clinched, i.e. so spread or bent, that the THT-components in their upside down position do not fall out of the circuit board but, instead, are held in their positions. The shortening of the connection wires, respectively connection pins, of the THT-components additionally means that they then extend only slightly out of the circuit board, so that they cannot interfere with a subsequent application 55 of the solder paste, preferably by means of printing. With long, protruding connection wires, respectively connection pins, there is the danger that they protrude into the plane of the printing screen required for the application of the solder paste or that they interfere with the positioning of the printing screen.

Naturally, it is also possible to secure particularly heavy THT-components or such with an unfavorable mass distribution by adhesive on the first side of the circuit board.

Following the dressing of the connection wires, or connection pins, as the case may be, of the THT-components, an automated populating 56 of SMD-components and then of PIH-components on the second side of the circuit board is performed. Preferably, such PIH-components are used, which can be held by a sort of “wet adhesive attraction” of the solder paste and which do not require any additional measures for securing them in their proper orientation and at the desired location. Then, the circuit board, now populated on the second side, is sent into a reflow oven of the invention, for example one such as is illustrated in FIG. 7, for soldering 58.

A reflow oven 60 shown in FIG. 7 includes a housing 61, which, similarly to the reflow oven 40 shown in FIG. 5, is divided into a plurality of chambers 62. In most of the chambers 62, heat exchangers 63 and blowers 64 are provided, in order to control the heat flux in the reflow oven 60 and in order thereby to heat the circuit board(s) 66 in desired manner, before the actual soldering and to bring the energy needed for the soldering to and onto the circuit board(s). In contrast to the conventional reflow oven 40 of FIG. 5, the circuit boards are arranged on frames 67 or similar structures on the conveyor belt 65. These frames 67 enable a greater separation than usual, of the circuit boards 66 from the conveyor belt, so that, for circuit boards 66 populated on the first side with relatively bulky THT or other “exotic” and thermally critical components, such as, for example, the transformers 2, plugs 7 or rotary switches 5 of the circuit board of FIG. 1, such components find room between the conveyor belt 65 and the circuit boards 66, despite their size. In the case of conventional reflow ovens, the space between conveyor belt and circuit board is designed only for SMD-components, so that relatively large THT-components can only be soldered on the side of the circuit boards facing the flow of heat energy. Then, however, as above-described, only such THT-components can be used, that have housings which are thermally resistant in the reflow oven. If no such THT-components are available, or they are too expensive, then the only remaining solution is to solder these components separately, for example manually, or in a wave soldering bath that permits dot-shaped soldering.

The invention allows, however, also THT-components with thermally critical housings and other items, such as THT-components which are themselves thermally sensitive, to be transported through the reflow oven 60 and soldered there. An essential idea in this is that the second sides of the circuit boards 66, thus there where soldering is to occur, are exposed to the action of the flow of heat energy required for the soldering, while their first sides, with the THT or other “exotic” and thermally critical components located thereon, face toward the conveyor belt 65. The circuit boards 66 themselves screen the thermally critical components against the heat energy. In order to achieve this, the circuit boards 66 are preferably, as shown in the case of the reflow oven 60 in FIG. 7, oriented horizontally, with the second side, which is to be soldered, facing upwards towards the incoming heat energy and the thermally critical components being located beneath the circuit boards 66. The thermally critical components are soldered, so-to-say, upside down, in conjunction with the soldering of the SMD- and PIH-components populated on the second sides of the circuit boards.

Depending on the space available in the individual chambers 62 of the reflow oven 60 and on the arrangement of the heat exchangers and blowers, the circuit boards can also be transported through the reflow oven arranged in some other way, provided that it is assured that the heat energy required for the soldering impinges in desired manner on the side of the circuit boards that is to be soldered and the circuit boards themselves cover the thermally critical components and shield them from the flow of heat energy. Thus, the heat sources, respectively feeds, can be arranged laterally in the reflow oven and caused to act from the side onto the side of the circuit boards to be soldered, with the circuit boards 66 being, in this scenario, inclined or even vertically arranged during transport through the reflow oven.

In comparison to the reflow oven 40 illustrated in FIG. 5, the reflow oven 60 shown in FIG. 7 has at least one quartz radiator 68. The one or more quartz radiators 68 permit lowering of the temperature existing in the chambers 62 serving for the soldering below a temperature otherwise required for the soldering of the components. The quartz radiators deliver an infrared radiation, which then makes available, as an additional energy radiation at the soldering locations on the side of the circuit boards 66 to be soldered, the energy required for the soldering. By this measure, the overall temperature existing in the reflow oven 60 is limited, both on the side to be soldered and on the opposite side of the circuit board 66, where the thermally critical components are. These components can be shielded still better by the circuit board 66 against the infrared radiation of the quartz radiator 68 used for the soldering.

It has been found that alone by arranging the thermally critical components on the first side of the circuit board 66, to thermally separate them by the circuit board 66 itself from the heat energy required for the soldering, a temperature difference between the first and second sides of the circuit board amounting from about 28° C. to about 35° C. can be achieved. In this connection, it is of advantage when the circuit board does not have too much copper, thus conductor paths, or traces, on the surface.

In the case of many components with a housing critical relative to the temperatures existing on the upper side of circuit boards during soldering, the above-mentioned temperature difference of 28 to 35° C. between the first and second sides of the circuit board is already sufficient for enabling the soldering of the thermally critical THT-components in the reflow oven, without damaging or destroying the housing, respectively the component itself, by the temperature. Should this temperature difference not be sufficient, it is, for example, possible to apply the blowers 64 and/or heat exchangers 63 located in the reflow oven 60 of FIG. 7 beneath the conveyor belt 65 in the last, or last two, exit-side chambers 62 for cooling of the downwardly directed, first side of the circuit board 66 and the thermally critical components located thereon. Additionally, it is also possible in the reflow oven of the invention illustrated in FIG. 7 to provide active cooling elements in the lower parts of the chambers. These cooling elements actively cool the thermally critical components located on the first, underlying sides of the circuit boards, for instance by means of a cooled air flow directed thereat. It is clear that these cooling measures require an efficient thermal separation between the to-be-soldered, second side of the circuit board and its first side. In doing this, however, attention must be paid that the achieved temperature difference between the first and the second sides of the circuit board does not lead to such stresses in the circuit board that the board destructs. The above-described infrared radiators 68 (see FIG. 7) are especially suited for an essentially dot-shaped heating of the circuit board at the locations to be soldered. With them, it is possible to set the average temperature on the total second side of the circuit board, whether with and without cooling, such that the temperature difference between first and second sides of the circuit board is exactly sufficient for preventing damage to the thermally critical components of the first side, without having dangerous heat stresses jeopardize the circuit board itself.

FIGS. 8 and 9 are schematic representations of preferred arrangements of various components on a circuit board of the invention. The drawing shows, in each case, such a circuit board 70, after having been soldered in a reflow oven, preferably in an oven of the invention, for example in a reflow oven 60 of FIG. 7.

On their first side 71, the circuit boards 70 shown here by way of example are populated by two different SMD-components 73a and 73b, which, for example, as described above, are the first components soldered in the reflow oven. The THT-resistances 75 and a THT angle plug 76 subsequently populated on the first side 71 (see FIG. 8) are soldered in the reflow oven following the turning of the circuit board 70 over and the populating of the second side 72 of the circuit board 70 with different SMD-components 74a and 74b, and, indeed, preferably in the horizontal position of the circuit board 70 as shown in FIG. 8. Here, the circuit board 70 itself serves as shielding of the thermally sensitive THT-resistances 75 and the angle plug 76 against the heat energy acting on the second side 72 of the circuit board 70.

It has been found that the described soldering method of the invention can also be used for soldering thermally critical PIH-components. This is depicted by the circuit board 70 in FIG. 9, where thermally critical PIH-resistances 78 and a PIH angle plug 79 are used, instead of the corresponding THT-components 75 and 76 of FIG. 8. For the PIH-components 78, 79 in FIG. 9, it must, however, be assured for an upside-down soldering in the reflow oven, that they do not fall out of the PIH solder locations, should the wet adhesive strength of the solder paste applied there not be sufficient to hold the PIH-components 78, 79 in an upside-down position before the soldering. The PIH-components 78, 79 can, for example, be secured with adhesive, or the PIH blind holes, in which the connection wires, respectively pins, of the PIH-components 78, 79 are stuck, are so arranged or so spaced for the individual PIH-components 78, 79, that the connection wires, respectively pins, of the PIH-components 78, 79 can be so bent, that they bind the PIH components 78, 79 in the PIH blind holes.

FIGS. 10a and 10b illustrate a special additional advantage achieved with the soldering- and populating-method of the invention in the case of soldering THT-components. FIG. 10a shows a circuit board 80 populated with a THT-component 81, whose connection wire 82 was stuck through a desired, metallized traverse hole 83, after such was first provided with a solder paste 84. The solder paste 84, which usually sits on the metallized traverse hole 83 in a kind of drop form and so closes the hole, gets punched through and divided when the connection wire 82 is stuck through the metallized traverse hole 83. A portion of the solder paste remains on the upper side of the metallized traverse hole 83, while the other portion forms a drop, or a sort of ball, on, or at, as the case may be, the tip of the connection wire 82.

In the case of a THT-component suited in this case for soldering in a usual reflow oven and charged into the reflow oven in the position illustrated in FIG. 10a, thus arranged above on the horizontally oriented circuit board, the solder paste 84 softens and flows due to the influx of heat in the reflow oven, and, frequently, the drop, or ball, of solder paste on the tip of the connection wire 82 drops off, due to the force of gravity. When the remaining solder paste 84 at the top of the metallized traverse hole 83 is not sufficient to fill the space between the connection wire 82 and the walls of the traverse hole 83, a faulty solder location can result.

The great advantage of the solder and populating method of the invention, wherein the THT-components, and especially thermally critical THT-components, can be soldered in the reflow oven upside-down, is to be seen in the result illustrated in FIG. 10 following soldering. In the reflow oven, the drop or ball of solder paste on the tip of the connection wire 82 flows under the action of the heat and the force of gravity back into the metallized traverse hole 83, where it solders cleanly and forms a secure solder location.

FIGS. 11 and 12 show a further embodiment of a circuit board 90 of the invention, and, indeed, during the soldering in a reflow oven, preferably a reflow oven of the invention. On the circuit board, in each case, in FIGS. 11 and 12, is populated a thermally sensitive, relatively heavy THT-component 91 having connection wires 94. Component 91, as described above, was secured on the circuit board 90 by adhesive dots 93, thus dots of suitable adhesive, before the circuit board 90 was placed in the reflow oven in the horizontal position shown in FIGS. 11 and 12. Without the adhesive, the relatively heavy THT-component 91 would fall from the circuit board 90. Use of adhesives in this way is always advantageous, when the THT-component 91 cannot be secured in the desired position on the circuit board 90 by other measures, such as, for example, by clinching of the connection wires 94 and by binding. These and other types of securement of such a THT-component are already described above.

[In order to achieve a temperature difference between the upper side of the circuit board 90, which is facing towards a feed of heat energy (indicated by arrows 96) required for the soldering, and the opposite, under side of the circuit board facing away from the feed of heat energy, that assures that the thermally critical components on the under side will not be damaged, various means 98, 99 of covering for the upper side of the circuit board can be used according to the invention, as illustrated in FIGS. 11 and 12.

There are basically two possibilities for setting the desired temperature difference required for protecting the thermally critical components 91 on the under side of the circuit board 90. On the one hand, the temperature arising on the upper side of the circuit board 90 from the feed 96 of heat energy can be set exactly to the minimum temperature required for the soldering of the selected solder paste. This permits, with appropriate layout of the circuit board, as above described, achievement of temperature differences between upper and under sides of the circuit board 90 of about 28° C. to 35° C. alone by the shielding effect of the circuit board itself. Since the soldering temperature was already set at the lower limit, this is already sufficient in some cases to prevent a damaging of the thermally critical components 91 on the under side of the circuit board 90.

If this is not sufficient, then there is the possibility of improving the thermal separation between the upper and lower sides of the circuit board 90. FIGS. 11 and 12 show two examples of coverings for this purpose. FIG. 11 schematically represents, by way of example, a covering mask 98, with which the “free” locations of the circuit board 90 between the connection wires 94 to be soldered are covered. In this way, the uptake of heat energy is essentially limited to the locations to be soldered and the chance of an excessive heating of the entire circuit board 90 is lessened. Less heat energy is available for passing to the thermally critical component 91 on the under side of the circuit board 90. Preferably, such a covering mask is made of a non-metallic material.

In contrast, the covering 99 presented in FIG. 12 covers exactly the locations of the circuit board 90 that are to be soldered, i.e. the locations of the connection wires 94, for example. It has been found in tests that a preferably metallic covering 99 of suitable thickness leads to a buildup of heat under the covering and thus at the connection wires 94 to be soldered, so that a higher temperature is achieved at soldering locations covered in this way, as compared to non-covered, free locations of the circuit board 90. This surprising effect of a locally above-average temperature increase on the circuit board enables a safe soldering of the soldering locations, i.e. the connection wires with the solder paste 97, despite a low, minimal feed of heat energy. In this way, the average heat energy uptake of the circuit board 90 can be lowered, as a whole, so that a thermal separation and temperature difference between the upper side and the under side of the circuit board 90 are obtained for protecting the thermally critical component 91.

### Translation of German Words in the Drawings

FIG. 4:
30 Solder Paste Application
31 SMD-Populating (Reflow Side)
32 Reflow Soldering Process
33 Adhesive Application
34 SMD-Populating (Wave Side)
35 SMD-Adhesive Hardening
36 Populating (Exotic) Components
37 Fluxing
38 Wave Soldering
evtl. Reinigung=Possible Cleaning

FIG. 6:
50 Solder Paste Printing
51 SMD-Populating
52 Reflow Soldering
53 Populating (Exotic) Components
54 Dressing
55 Paste Application
56 SMD-Populating
57 Populating PIH
58 Reflow Soldering

1-30. (canceled)

31. A method for populating and soldering a circuit board having a first side and a second side and at least one wired, electrical component (“THT-component”) having at least one connection wire or connection pin and a housing or casing thermally critical for conventional, automatic soldering technology, comprising the steps of:
populating the THT-component on the first side of the circuit board, with the connection wire or pin stuck from the first side through a hole and emerging on the second side of the circuit board in the area of a soldering contact surface printed with a solder paste; and
placing the circuit board so populated into a reflow oven for the soldering, wherein:
the first side populated with the THT-component is at least partially, essentially shielded from a heat or energy feed effecting the soldering.

32. A method for populating and soldering a circuit board having a first side and a second side and at least one wired, electrical component (“THT-component”) having at least one connection wire or connection pin and a housing or casing thermally critical for conventional, automatic soldering technology, comprising the steps of:
populating the THT-component on the first side of the circuit board, with the connection wire or pin stuck from the first side through a hole and emerging on the second side of the circuit board in the area of a soldering contact surface printed with a solder paste; and
placing the circuit board so populated into a reflow oven for the soldering, wherein:
the first side populated with the THT-component is thermally separated from the heat or energy feed acting on the second side of the circuit board for the soldering and
a temperature difference of at least 280C can be achieved between the first side and the second side.

33. The method as claimed in claim 31, further comprising the step of:
applying solder paste to solder contact surfaces provided on the second side of the circuit board for a populating of the second side of the circuit board with at least one SMD-component, wherein:
following populating of the second side of the circuit board with the SMD-component, it is soldered, together with the connection wire of the THT-component, in the reflow oven.

34. The method as claimed in claim 32, further comprising the step of:
applying solder paste to solder contact surfaces provided on the second side of the circuit board for a populating of the second side of the circuit board with at least one SMD-component, wherein:
following populating of the second side of the circuit board with the SMD-component, it is soldered, together with the connection wire of the THT-component, in the reflow oven.

35. The method as claimed in claims 31, wherein:
the first side of the circuit board is populated with at least one SMD-component.

36. The method as claimed in claims 32, wherein:
the first side of the circuit board is populated with at least one SMD-component.

37. The method as claimed in claim 35, further comprising the steps of:
printing of solder paste on the first side of the circuit board;
populating of the first side with SMD-components;
soldering the SMD-components of the first side in the reflow oven;
populating of the first side with at least one THT-component;
printing of solder paste on the second side;
populating the second side with SMD-components, and
soldering SMD-components of the second side and the one or more THT-components in the reflow oven.

38. The method as claimed in claim 37, wherein:
dressing the connection wires of the THF components before the printing of the solder paste on the second side of the circuit board.

39. The method as claimed in claim 38, wherein:
the connection wires of the THT-components are clinched or bent in some other way, such as being crimped, such that they clamp the one or more affected THT-components on the circuit board.

40. The method as claimed in claim 38, wherein:
the connection wires are shortened before the populating of the THT-components such that they extend only slightly from the circuit board after the populating.

41. The method as claimed in claim 37, wherein:
before the populating of the THT-components on the locations to be populated, adhesive for securing the THT-components on the circuit board is applied.

42. The method as claimed in claim 37, wherein:
on the circuit board and/or on at least one of the THT-components, at least one securement aid is provided, which secures the affected THT-component mechanically on the circuit board following the populating.

43. The method as claimed in claim 42, wherein:
the securement aid includes a snap-in mechanism.

44. The method as claimed in claim 35, further comprising the steps:
printing of solder paste on the first side;
applying adhesive on the locations of the first side which are to be populated with THT-components;
populating the first side with SMD-components;
populating the first side with THT-components;
soldering the SMD-components of the first side in the reflow oven;
printing solder paste on the second side;
populating the second side with SMD-components, and
soldering the components of the second side and the THT-components in the reflow oven.

45. The method as claimed in claim 44, wherein:
before the printing of the solder paste on the second side, connection wires of the THT-components are so dressed that they do not protrude beyond the surface of the circuit board.

46. The method as claimed in claims 31, wherein:
at least one of the sides of the circuit board is populated with at least one pin-in-hole component (PIH-component).

47. The method as claimed in claim 31, wherein:
the first side of the circuit board populated with the one or more THT-components is shielded, thermally separated, in the reflow oven essentially by the circuit board itself from the heat or energy feed acting on the second side for the soldering.

48. The method as claimed in claim 47, wherein:
in the case of an essentially horizontal arrangement of the circuit board during travel through the reflow oven for the soldering of the THT-components or the THT-component, these or this, as the case may be, are located underneath the circuit board.

49. The method as claimed in claim 31, wherein:
the first side of the circuit board populated with the one or more THT-components is cooled in the reflow oven.

50. The method as claimed in claim 31, wherein:
in the reflow oven, those areas of the circuit board, which have a tendency, because of a circuit board layout, to have an above-average take-up of heat energy, are covered with a covering that blocks or delays the uptake of heat energy.

51. The method as claimed in claim 50, wherein:
the covering is made of a non-metallic material.

52. The method as claimed in claim 31, wherein:
where an above-average heating by the heat or energy feed effecting the soldering in the reflow oven is desired in a region of the circuit board, this region of the circuit board is covered with a covering improving a heat energy uptake.

53. The method as claimed in claim 52, wherein:
the covering is made of a metallic material.

54. A reflow oven for soldering a circuit board having a first side and a second side and at least one wired, electrical component (“THT-component”) having at least one connection wire or connection pin and a housing or casing thermally critical for conventional, automatic soldering technology, comprising:
means to shield the first side of the circuit board populated with the THT-component during soldering, in the area of a solder contact surface printed with a solder paste, from a heat or energy feed effecting the soldering of the connection wire of the THT-component emerging at said surface.

55. A reflow oven for soldering a circuit board having a first side and a second side and at least one wired, electrical component (“THT-component”) having at least one connection wire or connection pin and a housing or casing thermally critical for conventional, automatic soldering technology, comprising:
means to shield the first side of the circuit board populated with the THT-component is thermally separated during the soldering, in the area of a solder contact surface printed with a solder paste, from a heat or energy feed effecting the soldering of the connection wire of the THT-component emerging at said surface, wherein:
a temperature difference between the first and second sides of at least 28° C. is achievable by suitable means.

56. A reflow oven as claimed in one of the claims 54, wherein:
the circuit board is arranged such that, during its transport through the reflow oven, the first side of the circuit board populated with the one or more THT-components is shielded, respectively thermally separated, essentially by the circuit board itself from the heat or energy feed acting on the second side of the circuit board for the soldering.

57. A reflow oven as claimed in one of the claims 55, wherein:
the circuit board is arranged such that, during its transport through the reflow oven, the first side of the circuit board populated with the one or more THT-components is shielded, respectively thermally separated, essentially by the circuit board itself from the heat or energy feed acting on the second side of the circuit board for the soldering.

58. The reflow oven as claimed in claim 54, further comprising:
a cooling apparatus provided therein, by means of which the side of the circuit board populated with the one or more THT-components is cooled during the soldering operation.

59. The reflow oven as claimed in claim 55, further comprising:
a cooling apparatus provided therein, by means of which the side of the circuit board populated with the one or more THT-components is cooled during the soldering operation.

60. The reflow oven as claimed in claim 51, further comprising:
at least one infrared radiation source, which delivers heat energy effecting the soldering.

61. A circuit board for the method as claimed in claim 31, such that it makes possible locally pre-determinable areas of above-average heat energy uptake in the case of heat energy acting externally onto the circuit board.

62. The circuit board as claimed in claim 61, wherein:
an above-average amount of copper is provided in the areas with desired above-average heat energy uptake.

63. The circuit board, as claimed in claim 61, wherein:
it is a multi-layer circuit board having at least one inner layer, which is so designed, respectively executed, that, in the areas of desired, above-average heat energy uptake, there is, in each case, a large-area, metallic and/or electrically conducting part.

64. The circuit board as claimed in claim 31, such that a below-average copper portion is provided in the areas where a below-average heat energy uptake is desired.
